(19) United States
(12) Patent Application Publication
(10) Pub. No.: US 2026/0181749 A1
(43) Pub. Date: Jun. 25, 2026

(54) SHOWERHEAD HEATING PACKAGE AND SUBSTRATE PROCESSING APPARATUS USING THE SAME

(71) Applicant: ASM IP Holding B.V., Almere (NL)

(72) Inventor: Koji Tanaka, Tokyo (JP)

(21) Appl. No.: 19/426,400

(22) Filed: Dec. 19, 2025

Related U.S. Application Data
(60) Provisional application No. 63/737,899, filed on Dec. 23, 2024.

(51) Int. Cl. H05B 6/10; H01J 37/32

(52) U.S. Cl. CPC H05B 6/108; H01J 37/3244; H01J 37/32522

(57) ABSTRACT

A showerhead heating package and a substrate processing apparatus using the same is presented. According to an embodiment of the present disclosure, a heating package for heating showerhead in a substrate processing apparatus, the heating package comprises: a showerhead heater disposed on a showerhead and embedded into the showerhead, the showerhead heater comprises: a heating element, a sheath surrounding the heating element, a filter configured to prevent radio frequency (RF) leakage from a heater line, a heater line configured to electrically connect the filter to the showerhead heater; and a ferrite core disposed on the heater line.

### CROSS-REFERENCE TO RELATED APPLICATIONS

This application claims priority to U.S. Provisional Patent Application Ser. No. 63/737,899 filed Dec. 23, 2024 titled SHOWERHEAD HEATING PACKAGE AND SUBSTRATE PROCESSING APPARATUS USING THE SAME, the disclosure of which is hereby incorporated by reference in its entirety.

### FIELD OF INVENTION

The present disclosure relates generally to a substrate processing apparatus, more particularly to a substrate processing apparatus with multiple heating packages which may heat up the showerhead with efficiency.

### BACKGROUND OF THE DISCLOSURE

Traditionally, showerhead heaters falter due to radio frequency (RF) power loss through the showerhead heater. The showerhead heater is usually inserted into the SHD via insulation and this insulation acts as a capacitor at high frequencies, Because of the insulation, the efficiency of the supplied RF can deteriorate.

An impedance of a capacitor can be measured by the (equation 1) shown below.

$${Z}_{C} = \text{} \frac{1}{j 2 π fC} ( {Z}_{c} : impedance of a capacitor , \\ j : imaginary unit , \text{} π : Constant Pi , \\ f : frequency , C : Capacitance ) \qquad ( equation 1 )$$

As shown in the above equation, the impedance (Z_{c}) is inversely proportional to the frequency (f). This means that as the frequency increases the impedance decreases and RF power loss increases throughout a showerhead heater due to the lowered impedance.

Therefore, the present disclosure presents an efficient showerhead heater package and a substrate processing apparatus equipped with the new showerhead heater package.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a heating package for heating showerhead in a substrate processing apparatus, the heating package comprises: a showerhead heater disposed on a showerhead and embedded into the showerhead, the showerhead heater comprises: a heating element, a sheath surrounding the heating element; a filter configured to prevent radio frequency (RF) leakage from a heater line; a heater line configured to electrically connect the filter to the showerhead heater; and a ferrite core disposed on the heater line.

In an aspect, the ferrite core is an inductor.

In an aspect, a length of the heater line is equal to or less than ⅛ of a wavelength of the RF, preferably equal to or less than 1/16 of the wavelength of the RF.

In an aspect, a length of the heater line is equal to or less than 30 cm.

In an aspect, the sheath is made of non-metallic material, the non-metallic material is one of alumina, quartz, aluminum nitride, boron nitride, mica, and engineering plastics.

In accordance with another embodiment there may be provided, a substrate processing apparatus comprising: a reaction chamber configured to process substrates, the reaction chamber comprising a showerhead for distribute plasma and gas for processing the substrates and a susceptor for supporting a substrate placed on it, and a process space is defined by the showerhead and the susceptor; and a number of heating packages, each of the heating package comprising: a showerhead heater disposed on a showerhead and embedded into the showerhead, the showerhead heater comprises: a heating element, a sheath surrounding the heating element; a filter configured to prevent RF leakage from a heater line; a heater line configured to electrically connect the filter to the showerhead heater; and a ferrite core disposed on the heater line.

In an aspect of the substrate processing apparatus, the ferrite core is an inductor.

In an aspect of the substrate processing apparatus, a length of the heater line is equal to or less than ⅛ of a wavelength of the RF, preferably equal to or less than 1/16 of the wavelength of the RF.

In an aspect of the substrate processing apparatus, a length of the heater line is equal to or less than 30 cm.

In an aspect of the substrate processing apparatus, the sheath is made of non-metallic material, the non-metallic material is one of alumina, quartz, aluminum nitride, boron nitride, mica, and engineering plastics.

In an aspect of the substrate processing apparatus, the number of heating packages is between 2 to 10.

In an aspect of the substrate processing apparatus, the heating packages are located at the same angle around upper side of the reaction chamber.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a simplified cross-sectional view of a substrate processing apparatus around the heating package according to an embodiment of the present disclosure.

FIG. 2 illustrates a simplified top view of a substrate processing apparatus showing the heating packages according to an embodiment of the present disclosure.

FIG. 3 illustrates a showerhead heater structure according to an embodiment of the present disclosure.

FIG. 4 illustrates a diagram of how filters and ferrite cores are placed with the heater packages according to an embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

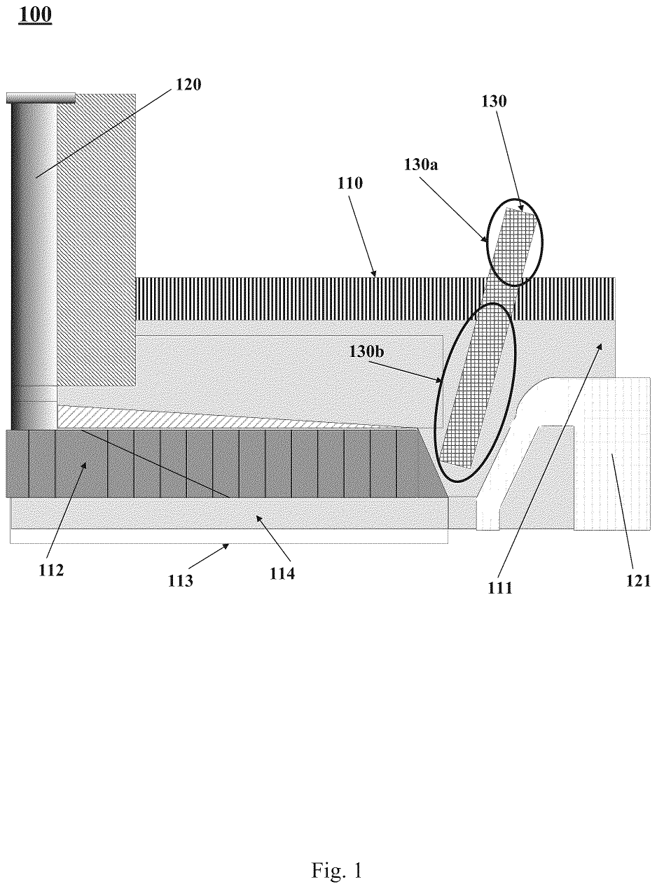

FIG. 1 illustrates a simplified side view of a substrate processing apparatus 100 according to an embodiment of the present disclosure.

The substrate processing apparatus 100 may comprise a reaction chamber 110. The reaction chamber 110 may be configured to process substrates and may also comprise a showerhead 112, and a susceptor 113. The reaction chamber 110 may also comprise a manifold 120 for injecting gas and a duct 121 with an exhaust port (not drawn) for exhausting gas from the reaction chamber 110.

The showerhead 112 may be configured to distribute plasma and gas, which are used to process the substrates. The susceptor 113 may be configured to support a substrate placed upon it. A process space 114 may be defined by the showerhead 112 and the susceptor 113. The process space 114 is where the plasma and gas may be distributed and reacted for processing substrates.

The reaction chamber 110 may also comprise a heating package 130 for heating up the showerhead 112. The heating package 130 may be partly positioned on an upper part of the reaction chamber 110 and also be partly inserted into the showerhead 112.

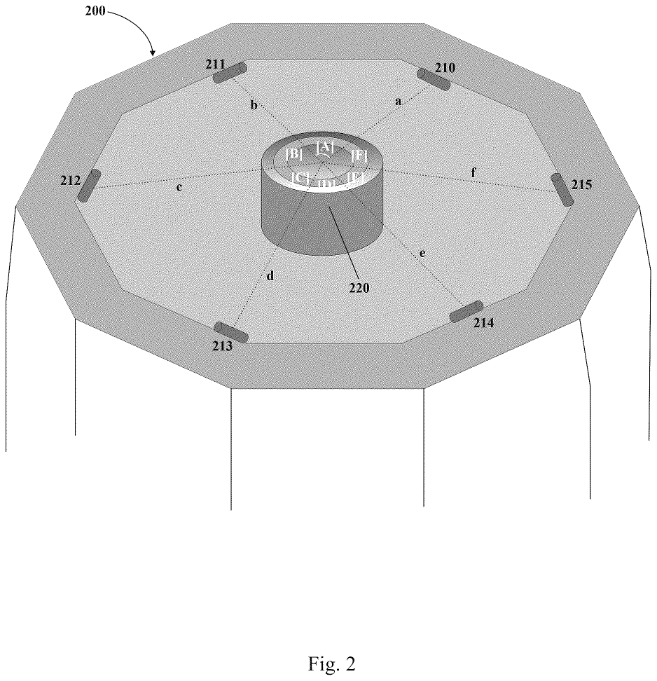

FIG. 2 illustrates a simplified top view of a reaction chamber 200 with heating packages according to an embodiment of the present disclosure. A manifold 220 may be located in the center of the reaction chamber.

In the upper side of the reaction chamber 200, there may be six heating packages 210, 211, 212, 213, 214, 215. Due to the conditions and requirements of the process, the number of heating packages may range between 2 and 10. As illustrated in FIG. 2, the number of heating packages is 6 and the heating packages 210, 211, 212, 213, 214, 215 equally distributed along an upper side of the reaction chamber 200.

When the number of heating packages is 6 as shown, an angle [A] from the line ‘a’ to the line ‘b’ may be 60 degrees since 360 divided by 6 is 60. A plurality of angles [B], [C], [D], [E], [F] may be all the same as the angle [A] to maximize the efficiency of the heating packages 210, 211, 212, 213, 214, 215. If the number of heating packages is 8, then the angle from a line to its neighbor line is 45 degrees (360° divided by 8).

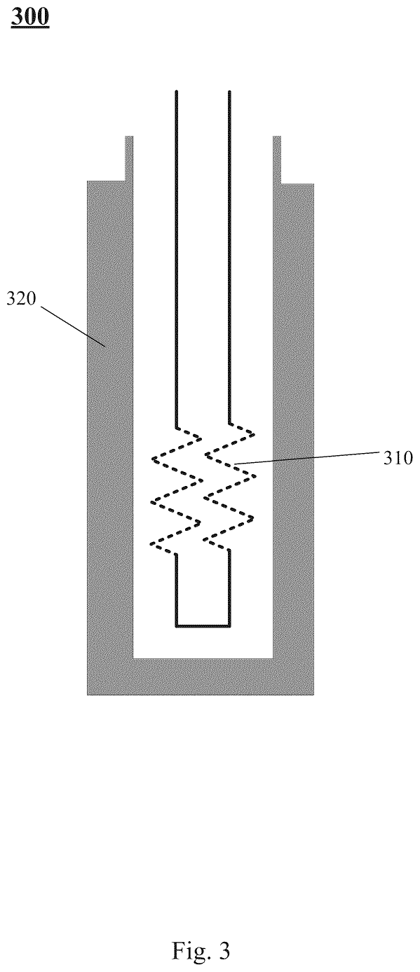

FIG. 3 illustrates a showerhead heater 300 according to an embodiment of the present disclosure.

As shown before, the showerhead heater 300 may be positioned deep down 130b to the level of showerhead 112. The showerhead 300 may comprise a sheath 320 and a heating element 310 disposed in the sheath 320. To minimize the RF power loss, the sheath 320 may comprise non-metal materials. The non-metal materials may comprise at least one of alumina, quartz, aluminum nitride, boron nitride, or mica. Engineering plastics may be also included in the non-metal materials if an operating temperature of the showerhead is low enough.

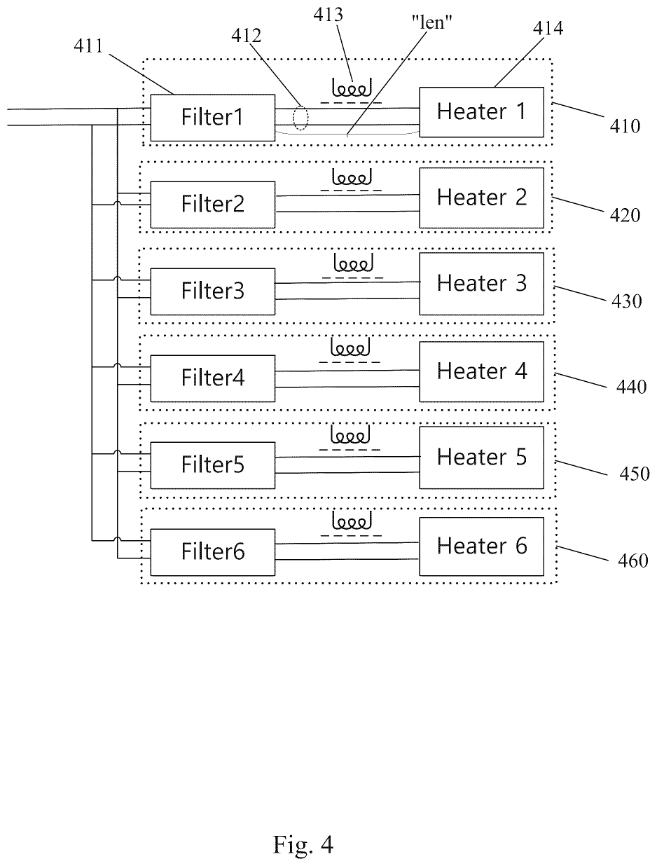

The non-metal material used for the sheath 320 may have a same effect as increasing the thickness of the insulator, as well as increasing the impedance of the sheath 320. To minimize the existing RF power loss, the present disclosure presents a heating package illustrated in FIG. 4. FIG. 4 illustrates a diagram of how the filters and ferrite cores are placed in the heater packages according to an embodiment of the present disclosure.

A heating package 410 may comprise a noise filter 411, a showerhead heater 414, a ferrite core 413, and a heater line 412 connecting the noise filter 411 to the showerhead heater 414.

The 5 other heating packages in FIG. 4, i.e., heating package 420, 430, 440, 450, 460, are also of the same structure as the heating package 410.

Even though the sheath 320 with non-metal material of the showerhead heater 300 may increase the impedance of the sheath 320, some RF power loss may exist since the shielding effect of the sheath 320 is lost (because the sheath 320 is not metal) and RF power is leaking to the heater line 412. To prevent the RF power leakage, the noise filter 411 may be placed.

Although the noise filter 411 may prevent some of the RF power leakage, the noise filter 411 may work poorly in high frequency environment, for example, a frequency higher than 30 MHz. To prevent this side effect, the ferrite core 413 is disposed at the heater line 412 to provide high impedance in the high frequency environment and the ferrite core 413 may be an inductor. If the ferrite core 413 is an inductor, the inductance (H) would be controlled and adjusted to meet the requirements of the ongoing process.

When RF power leaks into the heater line 412, the heater line 412 acts as an antenna and radiates RF into the air, and this radiation becomes stronger as the heater line 412 gets longer. So, it is better for a length of the heater line 412 (“len”) to be as short as possible so that the distance between the noise filter 411 and the showerhead heater 414 to be as close as possible. In general, RF emission, i.e., RF power loss, from cables may occur when the cable length is sufficiently long relative to a wavelength of the RF signal the cable carries.

The speed of electromagnetic wave (such as light) is a constant c, and its frequency (f0) and wavelength (λ0) are well known and given in (equation 2) below.

(equation 2) 10=c/f0 (c: speed of light, f0: frequency, λ0: wavelength)

Therefore, it is desirable for the heater line 412 (“len”) to have a length of less than ⅛ of the wavelength(λ), and preferably less than 1/16 of the wavelength so that the RF power loss from the heater line 412 to be lowered. Considering the frequency of the RF, 30 cm length of the heater line 412 may be good enough.

For an alternating current (AC), an impedance of an inductor is given in equation 3 below.

[equation 3] X_{L}=ωL(X_{L}: inductor's impedance, ω: angular frequency, L: inductance)

As shown in equation 3, an impedance of an inductor (or a ferrite core, for example) may increase as the frequency increases. Therefore, the higher the frequency gets, the higher the impedance gets and the ferrite core 413 disposed at the heater line 412 may provide a high impedance for high frequencies (>30 MHz). In addition to this, a noise filter 411 may be installed as close to the showerhead heater 414 as possible to prevent RF power loss and any outside interferences. The distance between the noise filter 411 and the showerhead heater 414 is the length of the heater line 412.

As explained above, the present disclosure's heating package is particularly effective in high frequency environments such as very high frequency (VHF) such as 30˜300 MHz.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A heating package for heating showerhead in a substrate processing apparatus, the heating package comprises:
a showerhead heater disposed on a showerhead and embedded into the showerhead, the showerhead heater comprises: a heating element, a sheath surrounding the heating element;
a filter configured to prevent radio frequency (RF) leakage from a heater line;
a heater line configured to electrically connect the filter to the showerhead heater; and
a ferrite core disposed on the heater line.

2. The heating package according to claim 1, wherein the ferrite core is an inductor.

3. The heating package according to claim 1, wherein a length of the heater line is equal to or less than ⅛ of a wavelength of the RF, preferably equal to or less than 1/16 of the wavelength of the RF.

4. The heating package according to claim 1, wherein a length of the heater line is equal to or less than 30 cm.

5. The heating package according to claim 1, wherein the sheath is made of non-metallic material, the non-metallic material is one of alumina, quartz, aluminum nitride, boron nitride, mica, and engineering plastics.

6. A substrate processing apparatus comprising:
a reaction chamber configured to process substrates, the reaction chamber comprising a showerhead for distribute plasma and gas for processing the substrates, and a susceptor for supporting a substrate placed on it, and a process space is defined by the showerhead and the susceptor; and
a number of heating packages, each of the heating package comprising:
a showerhead heater disposed on a showerhead and embedded into the showerhead, the showerhead heater comprises: a heating element, a sheath surrounding the heating element;
a filter configured to prevent RF leakage from a heater line;
a heater line configured to electrically connect the filter to the showerhead heater; and
a ferrite core disposed on the heater line.

7. The substrate processing apparatus according to claim 6, wherein the ferrite core is an inductor.

8. The substrate processing apparatus according to claim 6, wherein a length of the heater line is equal to or less than ⅛ of a wavelength of the RF, preferably equal to or less than 1/16 of the wavelength of the RF.

9. The substrate processing apparatus according to claim 6, wherein a length of the heater line is equal to or less than 30 cm.

10. The substrate processing apparatus according to claim 6, wherein the sheath is made of non-metallic material, the non-metallic material is one of alumina, quartz, aluminum nitride, boron nitride, mica, and engineering plastics.

11. The substrate processing apparatus according to claim 6, wherein the number of heating packages is between 2 to 10.

12. The substrate processing apparatus according to claim 11, wherein the heating packages are located at the same angle around an upper side of the reaction chamber.
